(19) United States
(12) Patent Application Publication
(10) Pub. No.: US 2013/0234742 A1
(43) Pub. Date: Sep. 12, 2013

(54) INTEGRATED CIRCUIT AND PRINTED CIRCUIT BOARD HAVING RECEIVER TESTING FUNCTION

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventor: FA-SHENG HUANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/720,924

(22) Filed: Dec. 19, 2012

(30) Foreign Application Priority Data
Mar. 9, 2012 (CN) 201210061010.7

(51) Int. Cl. G01R 31/28

(52) U.S. Cl. CPC G01R 31/2841
USPC 324/750.01

(57) ABSTRACT

A integrated circuit having a receiver testing function includes a signal generating circuit, a jitter output circuit, a signal mix circuit, a receiver, and an error counting circuit. The signal generating circuit outputs a reference signal to the signal mix circuit and the error counting circuit. The jitter output circuit outputs a jitter. The signal mix circuit injects the jitter into the reference signal, and outputs a testing signal that is a combination of the jitter and the reference signal. The receiver receives and then outputs the testing signal to the error counting circuit. The error counting circuit tests a performance of the receiver by determining whether a difference between a code information of the testing signal and a code information of the reference signal is within a predetermined difference range.

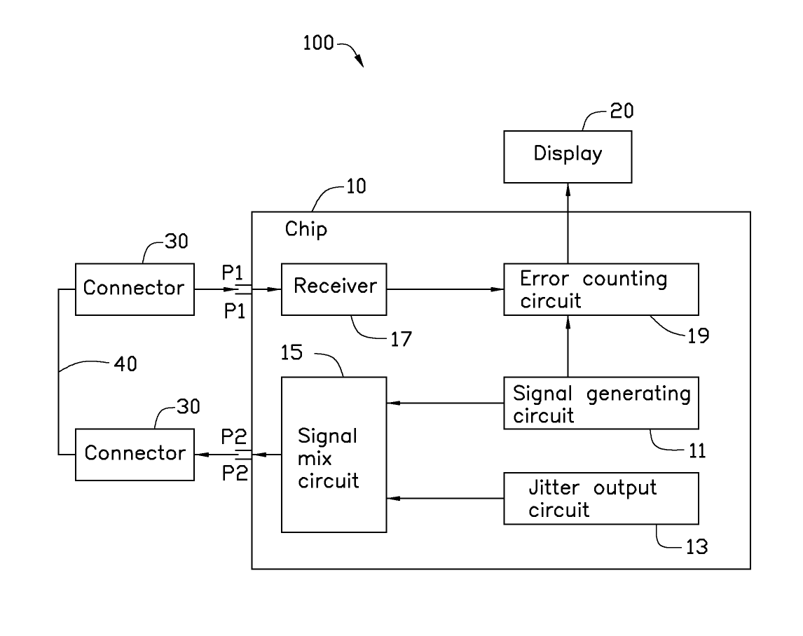

### BACKGROUND

1. Technical Field

The disclosure generally relates to integrated circuits, and particularly to a integrated circuit having a receiver testing function and a printed circuit board comprising same.

2. Description of Related Art

A integrated circuit usually comprises a receiver to receive signals, where performance of the receiver can be tested with a special test machine. However, the special test machine may be expensive which will increase cost testing of the receiver.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the disclosure.

The FIGURE shows a block diagram of an exemplary embodiment of a printed circuit board having a receiver testing function.

### DETAILED DESCRIPTION

The FIGURE shows a block diagram of an exemplary embodiment of a printed circuit board 100 having a receiver testing function. The printed circuit board 10 includes an integrated circuit 10, a display 20, two connectors 30, and a cable 40. The integrated circuit 10, the display 20, and the connectors 30 are mounted on the printed circuit board 100. The integrated circuit 30 includes at least one input pin P1 electronically connected to one of the two connectors 30, and at least one output pin P2 electronically connected to the other one of the two connectors 30. The cable 40 electronically connects between the two connectors 30. In the exemplary embodiment, the integrated circuit 30 comprises two input pins P1, and two output pins P2. The input and output pins P1 and P2 are electronically connected to the two connectors 30 via two differential pairs of transmission lines, respectively.

The integrated circuit 10 further includes a signal generating circuit 11, a jitter output circuit 13, a signal mix circuit 15, a receiver 17, and an error counting circuit 19. The signal mix circuit 15 is electronically connected to the signal generating circuit 11 and the jitter output circuit 13. The signal mix circuit 15 is further electronically connected to one of the two connectors 30 via the output pin P2. The receiver 17 is electronically connected to the other one of the two connectors 30 via the input pins P1. The error counting circuit 19 is electronically connected to the receiver 17 and the signal generating circuit 11.

The signal generating circuit 11 generates and outputs a reference signal to the signal mix circuit 15 and the error counting circuit 19. The reference signal can be one of a serial advanced technology attachment (SATA) signal, a peripheral component interconnect-express (PCIE) signal, a serial attached small computer system interface (SAS) signal, and a direct media interface (DMI) signal.

The jitter output circuit 13 generates and outputs a jitter to the signal mix circuit 15.

The signal mix circuit 15 injects the jitter into the reference signal, and outputs a testing signal, that is a combination of the jitter and the reference signal, to the connector 30 connected to the signal mix circuit 15. The jitter functions as an interference signal, which can change an amplitude or a phase of one or more codes of the reference signal, thereby forming the testing signal. In the exemplary embodiment, the testing signal and the reference signal includes a plurality of first codes and second codes, respectively, the testing signal has a same data format and transmission rate as a data form and transmission rate of the reference signal, while one or more codes of the first codes are different from corresponding codes of the second codes. In other words, the testing signal has a low signal quality (e.g. with error message) relative to the reference signal.

The receiver 17 receives the testing signal from the signal mix circuit 15 via the cable 40 and the two connectors 30, and transmits the received testing signal to the error counting circuit 19.

The error counting circuit 19 determines whether a difference between a code information of the testing signal and a code information of the reference signal is within a predetermined difference range, and outputs a result of the determination to the display 20. When the difference between the code information of the testing signal and the code information of the reference signal is within a predetermined difference range, the error counting circuit 19 determines performance of the receiver 17 is within requirements. When the difference between the code information of the testing signal and the code information of the reference signal is outside the predetermined difference range, the error counting circuit 19 determines the performance of the receiver 17 is not within requirements.

It is to be understood that, the connectors 30 can be omitted, and the input pins P1 can be physically and electronically connected to the output pins P2 directly via the cable 40.

The signal generating circuit 11, the jitter output circuit 13, the signal mix circuit 15 and the error counting circuit 19 are all integrated into the integrated circuit 10, such that the integrated circuit 10 can serve as a substitute for a special test machine to test the receiver 17, and thus decrease a testing cost.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An integrated circuit, comprising:
a signal generating circuit outputting a reference signal;
a jitter output circuit outputting a jitter;
a signal mix circuit electronically connected to the signal generating circuit and the jitter output circuit, the signal mix circuit injecting the jitter into the reference signal, and outputting a testing signal that is a combination of the jitter and the reference signal;
a receiver receiving and then outputting the testing signal; and
an error counting circuit electronically connected to the signal generating circuit and the receiver, the error counting circuit receiving the reference signal from the signal generating circuit and the testing signal from the receiver, and testing a performance of the receiver by determining whether a difference between a code information of the testing signal and a code information of the reference signal is within a predetermined difference range.

2. The integrated circuit of claim 1, wherein the testing signal and the reference signal comprises a plurality of first codes and second codes, respectively; the testing signal comprises a same data format and transmission rate as a data format and transmission rate of the reference signal, while one or more codes of the first codes are different from corresponding codes of the second codes.

3. The integrated circuit of claim 2, wherein the reference signal is one of a serial advanced technology attachment (SATA) signal, a peripheral component interconnect-express (PCIE) signal, a serial attached small computer system interface (SAS) signal, and a direct media interface (DMI) signal.

4. A printed circuit board, comprising:
a integrated circuit, comprising:
a signal generating circuit outputting a reference signal;
a jitter output circuit outputting a jitter;
a signal mix circuit electronically connected to the signal generating circuit and the jitter output circuit, the signal mix circuit injecting the jitter into the reference signal, and outputting a testing signal that is a combination of the jitter and the reference signal;
a receiver receiving and then outputting the testing signal;
an error counting circuit electronically connected to the signal generating circuit and the receiver, the error counting circuit receiving the reference signal from the signal generating circuit and the testing signal from the receiver, and testing a performance of the receiver by determining whether a difference between a code information of the testing signal and a code information of the reference signal is within a predetermined difference range; and
a display electronically connected to the error counting circuit, the display displaying a detection result of the error counting circuit.

5. The printed circuit board of claim 4, further comprising a cable, wherein the integrated circuit further comprises at least one input pin electronically connected to the receiver, and at least one output pin electronically connected to the signal mix circuit, the cable is electronically and physically connected between the at least one input pin and the at least one output pin, the testing signal is transmitted from the signal mix circuit to the receiver via the at least one output pin, the cable, and the at least one input pin.

6. The printed circuit board of claim 4, further comprising two connectors and a cable connected between the two connectors, wherein the integrated circuit further comprises at least one input pin electronically connected to the receiver and one of the two connectors, and at least one output pin electronically connected to the signal mix circuit and the other one of the connector, the testing signal is transmitted from the signal mix circuit to the receiver via the at least one output pin, the two connectors, the cable, and the at least one input pin.

7. The printed circuit board of claim 4, wherein the testing signal and the reference signal comprises a plurality of first codes and second codes, respectively; the testing signal comprises a same data format and transmission rate as a data form and transmission rate of the reference signal, while one or more codes of the first codes are different from corresponding codes of the second codes.

8. The printed circuit board of claim 7, wherein the reference signal is one of a SATA signal, a PCIE signal, a SAS signal, and a DMI signal.
